(19) United States
(12) Patent Application Publication
(10) Pub. No.: US 2002/0158344 A1
(43) Pub. Date: Oct. 31, 2002

(54) Configuration with at least two stacked semiconductor chips and method for forming the configuration

(76) Inventors: Uta Gebauer, Munchen (DE); Jens Pohl, Bernhardswald (DE)

Correspondence Address: LERNER AND GREENBERG, P.A., POST OFFICE BOX 2480, HOLLYWOOD, FL, 33022-2480, US

(21) Appl. No.: 10/132,805

(22) Filed: Apr. 25, 2002

(30) Foreign Application Priority Data
Apr. 27, 2001 (DE) 101 20 917.7

(51) Int. Cl. H01L 23/48; H01L 23/52; H01L 29/40

(52) U.S. Cl. 257/786

(57) ABSTRACT

A configuration containing stacked semiconductor chips, which have in each case an active front side with semiconductor structures and a passive rear side. Raised locations are provided on the active front side of each semiconductor chip and correspond to depressions on the rear side of a directly adjacent semiconductor chip. The raised locations are adhesively bonded and/or soldered to the corresponding depressions. A method for producing the configuration is also described.

### BACKGROUND OF THE INVENTION

### FIELD OF THE INVENTION

The invention relates to a configuration with at least two stacked semiconductor chips and a method for their production.

To obtain electronic semiconductor devices which are as compact as possible, single or multiple semiconductor chips can be stacked one on top of the other. The stacking may take place on the wafer level, with the semiconductor wafers being separated into individual assemblies of stacked semiconductor chips after the stacking. However, the stacking of the semiconductor chips that have already been individually separated is also possible. In the case of each of the stacking variants, it is essential to align and center the semiconductor wafers or chips exactly in relation to one another, in order that wirings and connections disposed in the middle of or at the edge of the chips come to lie over one another as exactly as possible. Examples of possible connections of this type are metallized drill holes or apertures (known as vias).

During the stacking of the semiconductor wafers or chips, it is possible to utilize for the electrical and mechanical contacting the capillary effect of a solder, which is intended to flow upward along the liners on account of the wetting effect on the metal. If, however, the metallized liners are offset in relation to one another, the solder cannot wet the liners over all the stacking levels. In the worst case, this results in defective or completely absent connections. To ensure the exact positioning, the semiconductor chips or wafers can be aligned in relation to one another with the aid of optical centering marks. After placing them on one another, they can be fixed by adhesive bonds and subsequently soldered to one another.

### SUMMARY OF THE INVENTION

It is accordingly an object of the invention to provide a configuration with at least two stacked semiconductor chips and a method for forming the configuration that overcome the above-mentioned disadvantages of the prior art devices and methods of this general type, which has a simple and low-cost way of mechanically centering the semiconductor wafers or chips to be stacked.

With the foregoing and other objects in view there is provided, in accordance with the invention, a configuration. The configuration contains at least two semiconductor chips stacked one upon another. Each of the semiconductor chips has an active front side with semiconductor structures and a passive rear side without any of the semiconductor structures. The passive rear side has at least two depressions formed therein. At least two raised locations are disposed on the active front side of each of the semiconductor chips. The raised locations correspond to the depressions on the passive rear side of a directly adjacent one of the semiconductor chips. Each of the raised locations are adhesively bonded and/or soldered to a corresponding one of the depressions.

According to the invention, the configuration contains at least two stacked semiconductor chips that have in each case an active front side with semiconductor structures and a passive rear side without semiconductor structures. In this case, there are at least two raised locations on the active front side of each semiconductor chip, corresponding to at least two depressions on the rear side of a directly adjacent semiconductor chip. According to the invention, it is provided that the raised locations are adhesively bonded and/or soldered to the corresponding depressions.

The configuration according to the invention has the advantage that an exact and reliable positioning of the semiconductor chips to be stacked one on top of the other can be ensured in a mechanical way, so that the subsequent processing steps, such as for example the establishment of contact connections, can be carried out reliably and with the lowest defect rate. The semiconductor chips corresponding to one another, with at least two depressions and raised locations in each case, ensure both exact positioning of the chips over one another and an exactly defined spatial distance between them, which may, however, also be zero if need be. In other words, the semiconductor chips may also be stacked one on top of the other with physical contact between them. The subsequent adhesive bonding or soldering of the connecting or centering locations to one another ensures a mechanically stable connection of a desired number of stacked semiconductor chips, which can subsequently run through further process steps without any problems. In the case of each semiconductor chip, it is also possible for more than two such centering locations to be provided, for example three or four. In this case, a possibly desired distance between two semiconductor chips can also be set better.

In one embodiment of the invention, it is provided that the depressions taper in the manner of a hollow cone, starting from the surface of the passive rear side, and have a flat base. This embodiment has the advantage of a centering effect, since the raised locations on the opposing side can be aligned centrally in the hollow-cone-shaped depressions and thus ensure optimum positioning of the semiconductor chips in relation to one another.

In one embodiment of the invention, the raised locations have a hemispherical or frustoconical contour, accompanied by the advantage of still better centering of the semiconductor chips to be stacked in relation to one another. Even when the semiconductor chips are not aligned exactly over one another, the raised locations finally slide nevertheless into exactly the correct position, since they are restrictedly guided in the hollow-cone-shaped depression on account of their hemispherical or frustoconical contour, and in this way come to lie exactly centrally in the depression.

In a further embodiment according to the invention, the cone angles of the hollow-cone-shaped depressions and of the frustoconical raised locations are approximately equal. This is accompanied by the advantage of an optimally matching positively locking mechanical connection. With equal cone angles, the raised locations lie exactly with a positive fit in the depressions and lead to very accurate alignment of the semiconductor chips in relation to one another.

A further embodiment according to the invention provides that a semiconductor chip has in each case at least three connecting locations containing depressions and corresponding raised locations in relation to each adjacent further semiconductor chip. This embodiment has the advantage of still better guidance of the semiconductor chips in relation to one another. Moreover, in this way a possibly desired spatial distance between the semiconductor chips to be stacked can also be set.

According to one embodiment of the invention, the depressions in the passive rear side of each semiconductor chip are provided by etching, which has the advantage of making production simple, if need be at the same time with a further etching step in the production of the semiconductor chips or wafers. Moreover, the depressions produced by an etching operation can be produced very precisely and dimensionally correctly, which is absolutely necessary for optimum matching of multiple stacked semiconductor chips.

According to a further embodiment of the invention, the raised locations on the active front side of each semiconductor chip are applied by a printing process, accompanied by the advantage of very exact dimensional accuracy and good reproducibility of the process.

One embodiment according to the invention provides that the raised locations on the active front side of each semiconductor chip are applied by developing out film layers. This embodiment has the advantage of making production of the raised locations simple and quick, since they can, if need be, be produced in one processing step at the same time as the further structures on the semiconductor chip.

In an alternative embodiment of the invention, the raised locations on the active front side of each semiconductor chip are formed as solder depots. This alternative embodiment has the advantage of a connection that can be established extremely simply and quickly, since the solder depots can be applied in a simple way and since no fixed raised locations have to be produced on the active front sides of the semiconductor chips. By melting the solder depots, they are centered of their own accord in the corresponding depression.

One embodiment of the invention provides that the hollow-cone-shaped depressions are respectively larger in diameter than the solder depots. As a result, when the semiconductor chips are placed on one another, the solder paste depots are pressed slightly apart and a contact is established with a metallized base of the depression of the semiconductor chip lying there-above. During the liquefying of the solder, the connecting locations are centered of their own accord with respect to one another.

In one embodiment according to the invention, the solder depots are respectively applied to contact areas, that is accompanied by the advantage of a good mechanical connecting location which can be subjected to high loading.

In a further embodiment according to the invention, the base of each hollow-cone-shaped depression is metallized. This has the advantage of a good mechanical connecting location. Moreover, the connecting locations can, if need be, be additionally used for the electrical connection of semiconductor chips stacked one on top of the other. This allows, in particular, relatively great current intensities to be passed through these connections with their relatively large cross sections.

One embodiment according to the invention provides that at least two semiconductor chips are securely joined to one another by melting the solder depots positioned in the respectively corresponding depressions. This embodiment according to the invention has the advantage of a stable mechanical connection between two semiconductor chips, which is suitable for the stacking of multiple semiconductor chips. A large number of stacked semiconductor chips are also held together very stably.

Finally, one embodiment of the invention provides that the stacked semiconductor chips are joined together at the wafer level. This is accompanied by the advantage of making it simple to handle the still undivided semiconductor wafers, which can already in this state be combined to form larger units of stacked wafers. The stacked wafers can then be subsequently separated into individual electronic devices containing stacked semiconductor chips. This procedure has the advantage of making it possible for processing to be carried out quickly, and consequently at low cost, since the handling on the wafer level makes it possible for the processing machines to operate with a much higher throughput.

A method according to the invention for producing an configuration with at least two stacked semiconductor chips, which have in each case an active front side with semiconductor structures and raised locations applied thereupon and a passive rear side with depressions provided therein, provides that the raised locations of a semiconductor chip respectively correspond to the depressions of an adjacent further semiconductor chip and are joined together with the depressions. According to the invention, the method has at least the following method steps. After providing semiconductor wafers with semiconductor chips disposed in rows and columns and sawing track regions provided in between, raised locations are applied to the active front sides of each wafer. Before or after this, depressions are provided in the passive rear sides of each semiconductor wafer. After the stacking of at least two semiconductor wafers, the establishment of secure connections between the raised locations and the depressions respectively corresponding to them takes place.

The method according to the invention has the advantage of very exact positioning of the semiconductor wafers to be stacked in relation to one another, so that the electrical connections of the wafers to one another to be produced in subsequent processing steps can achieve very high accuracy with a very low defect rate. On account of the mechanical centering by the raised locations and the depressions corresponding to them, no further centering and fixing measures are required any longer.

According to one embodiment of the method according to the invention, the semiconductor wafers are stacked and joined together before they are separated into individual semiconductor chips. The method has the advantage of making processing on the wafer level quick, and consequently low in cost, which permits a much higher throughput than handling semiconductor chips which have already been individually separated.

According to an alternative embodiment of the method according to the invention, the semiconductor wafers are initially separated into individual semiconductor chips and these are subsequently stacked. This alternative method has the advantage that different semiconductor chips can be individually stacked. The possibility of being able to process the already individually separated semiconductor chips permits much more flexible production of a wide variety of electronic components from stacked semiconductor chips.

In a further embodiment of the method according to the invention, the semiconductor wafers or semiconductor chips are stacked by adhesively bonding the raised locations in the corresponding depressions. This is accompanied by the advantage that mechanical fixing of the stacks can be established in a very simple way. Adhesive bonds can be cured either after a certain time or, for example, by slight heating. In comparison with soldering of the connecting locations, adhesive bonding is a more gentle process.

A further exemplary embodiment of the method according to the invention provides that the semiconductor wafers or the semiconductor chips are stacked by soldering the raised locations in the corresponding depressions. This method has the advantage of a very stable mechanical connection, which is suitable moreover for the transmission of electric signals. Consequently, if need be, the mechanical connections can be used as additional electrical connections between the stacked semiconductor chips.

In one exemplary embodiment of the method, the solder depots acting as raised locations are melted in the depressions when the semiconductor wafers or semiconductor chips have been stacked. This method has the advantage that the solder depots, which are formed for example from solder paste, can be applied to the contact locations in a simple way and ensure stable centered connection during subsequent melting.

Finally, an example of how the method can be carried out according to the invention provides that the joining locations are centered with respect to one another during the melting of the solder. This is accompanied by the advantage that no further centering measures are required. Moreover, the raised locations do not have to be exactly configured, but instead the solder paste depots just have to drop approximately into the depressions, where they ensure filling of these depressions, and automatic centering therein, during the subsequent melting.

To sum up, the following aspects of the invention are obtained. A first variant for positioning the wafers or the individually separated semiconductor chips in relation to one another provides centering by a “plug-and-socket” principle. For this purpose, an elevation is applied on the side of the active structures of the semiconductor chip, for example by a printing process or by developing out film layers. On the rear side of the wafer to be stacked, a notch or depression is respectively created at the corresponding locations, which may be performed for example by an etching operation. The depression corresponds to the corresponding elevation, both in terms of its position and in terms of its contour. If two wafers or two semiconductor chips are then placed on one another, a mechanical self-centering effect occurs, the positioning accuracy being extremely high, in particular if photolithographic processes are used for creating the connecting locations.

It is possible to dispense with additional mechanical fixing of the joined individual parts if stacking is directly followed by contacting by solder in further connecting locations, for example in liners, since the solder then keeps the wafers or the semiconductor chips on one another. Otherwise, fixing may be performed, for example, by an adhesive bond, which is only activated by suitable process steps after the centering.

A second variant of the connection provides that solder paste depots are applied on the active sides of the semiconductor chips, on corresponding contact areas. The semiconductor chips or wafers to be stacked have on their passive rear sides corresponding depressions, the base of which is metallized. The depressions are expediently slightly wider than the solder depots, but for that slightly lower. The semiconductor chips or wafers can then be placed on one another, the solder paste depot being pressed wide and contact being established with the metallized base in the depression of the adjacent chip or wafer. Since the depression is wider than the solder depot, the solder paste can escape correspondingly when the pressure is applied. If, after that, the solder paste is melted, a self-centering effect occurs between the contact area, the solder paste and the metallized base of the depression. At the same time, the solder serves for fixing the stacked components.

The advantage of both variants lies in the automatic and exact centering of the semiconductor wafers or chips to be stacked.

Other features which are considered as characteristic for the invention are set forth in the appended claims.

Although the invention is illustrated and described herein as embodied in a configuration with at least two stacked semiconductor chips and a method for forming the configuration, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWING

FIG. 1 is a diagrammatic, sectional view of two semiconductor chips to be stacked, in a first variant according to the invention;

FIG. 2 is a sectional view of the stacked semiconductor chips corresponding to FIG. 1;

FIG. 3 is a sectional view of the two semiconductor chips to be stacked, in a second variant according to the invention;

FIG. 4 is a sectional view of the two semiconductor chips according to FIG. 3 in a state in which they have been placed on one another;

FIG. 5 is a sectional view of the two semiconductor chips corresponding to FIG. 4 in a state of a secure connection; and

FIG. 6 is a sectional view of two semiconductor chips joined on top of one another by a conventional method.

### DESCRIPTION OF THE PREFERRED EMBODIMENTS

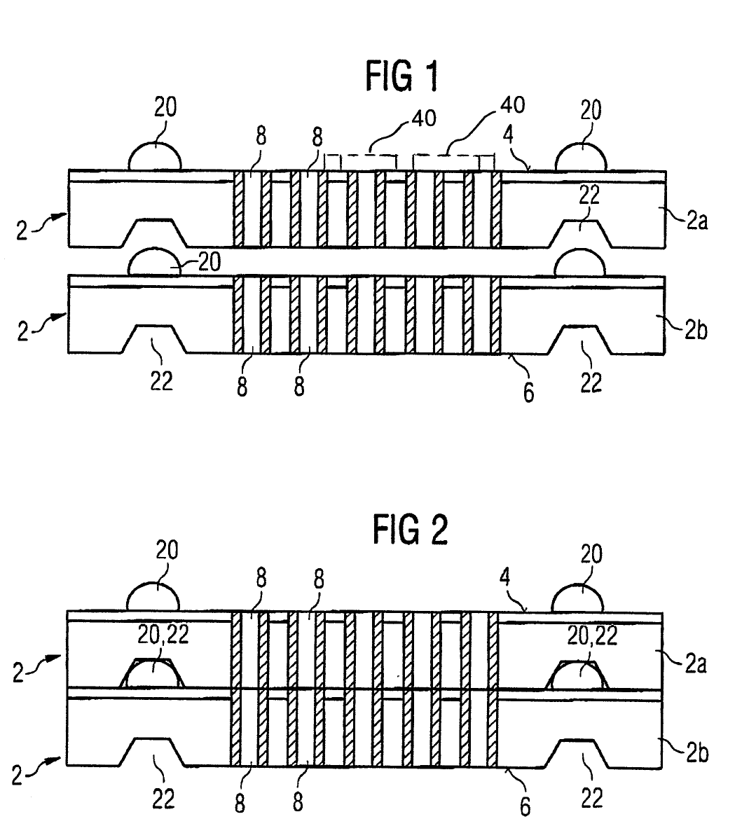

Referring now to the figures of the drawing in detail and first, particularly, to FIG. 1 thereof, there is shown a schematic sectional representation of two semiconductor chips 2 to be stacked, in a first variant according to the invention. An upper and a lower semiconductor chip 2a, 2b are disposed one on top of the other in such a way that their metallized apertures 8 are disposed congruently over one another and can be connected in this state by molten solder. The apertures 8 preferably have a cylindrical contour and are capable of transporting molten solder from the bottom to the top by a capillary effect. That is to say, multiple semiconductor chips 2 joined on top of one another can also be connected to one another via their apertures 8 by this method.

On an active front side 4, which is provided with semiconductor structures 40 (shown diagrammatically in dashed lines), each semiconductor chip 2 has at least two raised locations 20, which in the representation shown have a hemispherical contour. The raised locations 20 may, for example, consist of a metal that is suitable for soldering. Similarly, however, they may also be of a non-metallic configuration, and can then, for example, be adhesively bonded. In their passive rear sides 6, the semiconductor chips 2 are provided with depressions 22, which are produced, for example, by rear-side etching. The depressions 22 are preferably made so deep that the raised locations 20 can be accommodated in them. The raised locations 20 and the depressions 22 correspond to one another in such a way that each raised location 20 is accommodated in precisely one depression 22, to be precise in such a way that the semiconductor chips 2a and 2b are positioned exactly over one another, so that the apertures 8 lie congruently over one another. FIG. 2 shows this interrelationship.

In the exemplary embodiment shown, the depressions 22 are formed in the manner of hollow cones with a flat base. However, some other contour, for example a hollow-spherical contour, is similarly also possible. In the exemplary embodiment shown, the raised locations 20 are configured with a hemispherical contour. However, a frustoconical contour that fits exactly into the hollow-cone-shaped dpression 22 may also be similarly possible and advantageous.

The raised locations 20 may be adhesively bonded or soldered in the depressions 22, so that a mechanically stable connection between the semiconductor chips 2 is produced overall. In this way, multiple connections can be established between the semiconductor chips 2, so that even relatively large stacks, and consequently highly integrated electronic semiconductor devices, can be produced.

The connections represented may both exist between individual semiconductor chips 2 and be produced on the wafer level. Connections between entire semiconductor wafers which are separated into individual electronic assemblies only after stacking have the advantage of making processing quick, since a relatively high throughput can be achieved in this way.

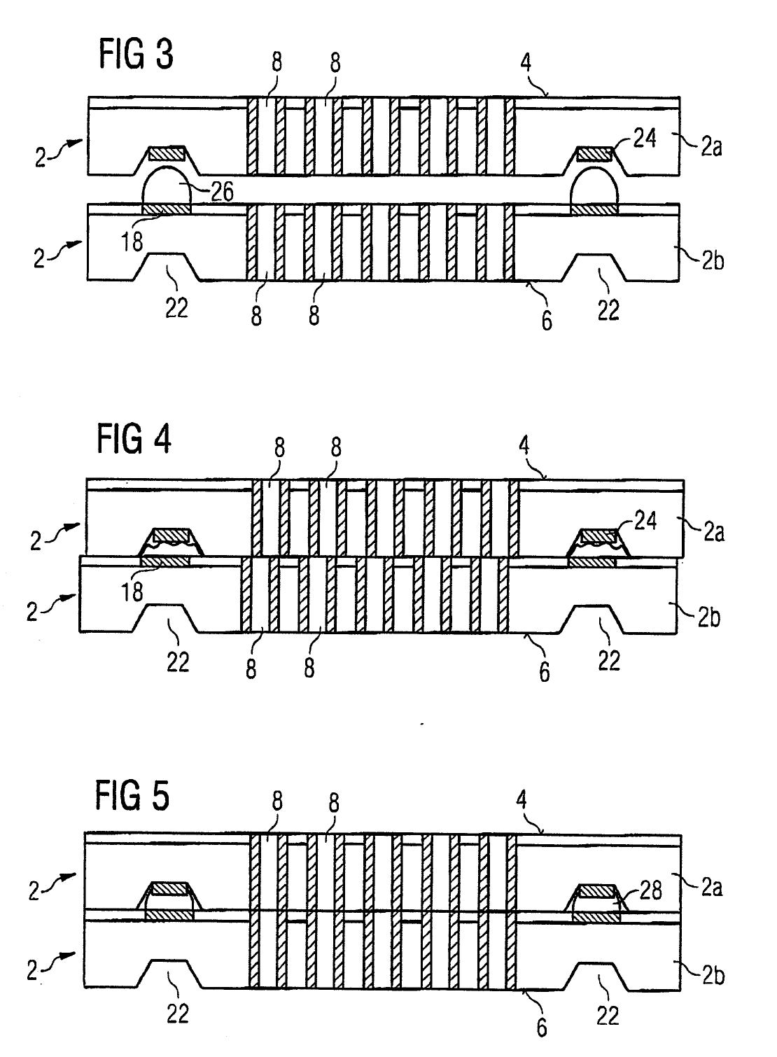

FIG. 3 shows a schematic sectional representation of two semiconductor chips 2 to be stacked, in a second variant according to the invention. As represented in the figures above, the upper semiconductor chip 2a is provided with depressions 22 in its passive rear side 6. The depressions 22 respectively have in their flat base a metal layer 24. The depressions 22 are themselves preferably configured in the manner of hollow cones, as is represented in FIGS. 3 to 5. On their active front sides 4, the semiconductor chips 2 are respectively provided with solder depots 26, which are preferably applied in each case on a metallic contact area 18. The solder depots 26 may be applied, for example, as solder paste and are located at those locations that correspond exactly to corresponding depressions 22.

The solder depots 26 approximately correspond in their diameter to the average diameter of the depressions 22, but are preferably slightly higher than the latter, so that they are deformed and pressed into the depression 22 when two semiconductor chips 2a, 2b are joined on top of one another, as can be seen in FIG. 4. As is also illustrated in FIG. 4, the lower and upper semiconductor chips 2b, 2a are not necessarily located exactly congruently one over the other, so that the through-connections 8 are in line with one another. They only come into line with one another when the solder depots 26 are melted by heating and ensure a secure soldered connection 28 between the lower and upper semiconductor chips 2b, 2a (FIG. 5). The surface tension of the liquid solder in this case causes it to bring about a central alignment in the depression 22, and consequently a self-centering effect, which displaces the semiconductor chips 2 in such a way that they are positioned exactly over one another.

The second variant according to the invention can also be produced both between individual semiconductor chips 2 and between complete semiconductor wafers.

A method according to the invention for producing the shown configuration of stacked semiconductor chips is explained below on the basis of FIGS. 1 to 5. The semiconductor chips 2 have in each case an active front side 4 with the semiconductor structures 40 and the raised locations 20 or solder depots 26 applied thereupon. They also have in each case the passive rear side 6 with the depressions 22 made therein, which may be provided, if need be, with the metal layer 24 in their base. According to the invention, it is provided that the raised locations 20 or the solder depots 26 of a semiconductor chip 2b respectively correspond to the depressions 22 of an adjacent further semiconductor chip 2a and are joined together with the depressions. According to the invention, the method has at least the following method steps. After producing the semiconductor chips 2 on the semiconductor wafers, with the semiconductor chips 2 disposed in rows and columns and sawing track regions provided in between, the raised locations 20 are applied to the active front sides 4 of each wafer. Before or after this, the depressions 22 are provided in the passive rear sides 6 of each semiconductor wafer. After the stacking of at least two semiconductor wafers, the establishment of secure connections between the raised locations 20 and the depressions 22 respectively corresponding to them takes place. Subsequently, the through-connections 8 can be filled with solder, which can rise from the bottom to the top over a plurality of semiconductor chips 2 on account of a capillary effect.

The method can be used on the one hand in the case of connecting semiconductor wafers that are subsequently separated into individual assemblies of stacked semiconductor chips 2. It is similarly possible for the semiconductor wafers to be separated into individual semiconductor chips 2, which are subsequently stacked to form larger electronic assemblies.

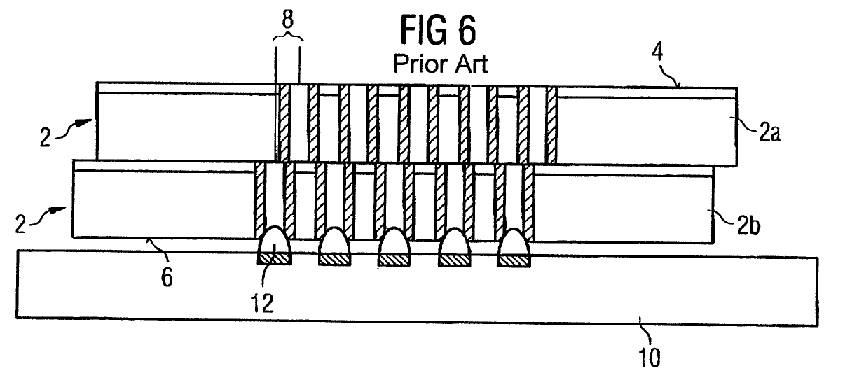

FIG. 6 finally shows a schematic sectional representation of the two semiconductor chips 2 joined on top of one another by a conventional method. These have no centering aids, so that under unfavorable conditions they can be easily displaced with respect to one another. In this case, the through-connections 8 are no longer exactly in line with one another, so that liquid solder rising from a support 10 for second solder depots 12 may no longer be capable of reaching the through-connections 8 of the next higher semiconductor chip 2 on account of the disturbed capillary effect. Consequently, however, connection of the chips during soldering is prevented. The support 10 may be, for example, a product printed circuit board or a sacrificial substrate.

We claim:

1. A configuration, comprising:
at least two semiconductor chips stacked one upon another, each of said semiconductor chips having an active front side with semiconductor structures and a passive rear side without any of said semiconductor structures, said passive rear side having at least two depressions formed therein; and
at least two raised locations disposed on said active front side of each of said semiconductor chips, said raised locations corresponding to said depressions on said passive rear side of a directly adjacent one of said semiconductor chips, each of said raised locations being at least one of adhesively bonded and soldered to a corresponding one of said depressions.

2. The configuration according to claim 1, wherein said depressions taper in a manner of a hollow cone, starting from a surface of said passive rear side, and have a flat base.

3. The configuration according to claim 1, wherein said raised locations have a contour selected from the group consisting of hemispherical contours and frustoconical contours.

4. The configuration according to claim 2, wherein:
said raised locations are frustoconical raised locations having a given angle; and
said depressions are hollow-cone-shaped depressions and have a cone angle approximately equal to said given angle of said frustoconical raised locations.

5. The configuration according to claim 1, wherein said semiconductor chips have in each case at least three connecting locations each formed of one of said depressions and a corresponding one of said raised locations in relation to each adjacent one of said semiconductor chips.

6. The configuration according to claim 1, wherein said depressions in said passive rear side of each of said semiconductor chips are formed by etching.

7. The configuration according to claim 1, wherein said raised locations on said active front side of each of said semiconductor chips are applied by a printing process.

8. The configuration according to claim 1, wherein said raised locations on said active front side of each of said semiconductor chips are applied by developing out film layers.

9. The configuration according to claim 1, wherein said raised locations on said active front side of each of said semiconductor chips are solder depots.

10. The configuration according to claim 9, wherein said depressions are hollow-cone-shaped depressions having a given diameter larger than a diameter of said solder depots.

11. The configuration according to claim 9, further comprising contact areas disposed on said active front surface, and said solder depots are respectively applied on said contact areas.

12. The configuration according to claim 10, wherein said hollow-cone-shaped depressions each have a base that is metallized.

13. The configuration according to claim 9, wherein said two semiconductor chips are securely joined to one another by melting said solder depots positioned in said depressions.

14. The configuration according to claim 1, wherein said semiconductor chips are joined together on a wafer level.

15. A manufacturing method, which comprises the steps of:
providing semiconductor wafers having semiconductor chips disposed in rows and columns and sawing track regions provided in between the semiconductor chips;
applying raised locations to an active front side of each of the semiconductor chips;
producing depressions in passive rear sides of each of the semiconductor chips;
stacking at least two of the semiconductor wafers above each other; and
establishing secure connections between the raised locations and the depressions respectively corresponding thereto.

16. The method according to claim 15, which comprises stacking and joining together the semiconductor wafers before they are separated into individual semiconductor chips.

17. The method according to claim 15, which comprises initially separating the semiconductor wafers into individual semiconductor chips and then stacking the individual semiconductor chips.

18. The method according to claim 15, which comprises
stacking the semiconductor wafers by adhesively bonding the raised locations in corresponding ones of the depressions.

19. The method according to claim 15, which comprises
stacking the semiconductor wafers by soldering the raised locations in the depressions.

20. The method according to claim 19, which comprises:
forming the raised locations as solder depots; and
melting the solder depots in the depressions when the semiconductor wafers have been stacked.

21. The method according to claim 20, which comprises
centering joining locations with respect to one another during the melting of the solder depots.

22. The method according to claim 17, which comprises
stacking the individual semiconductor chips by adhesively bonding the raised locations in corresponding ones of the depressions.

23. The method according to claim 17, which comprises
stacking the individual semiconductor chips by soldering the raised locations in the depressions.

24. The method according to claim 23, which comprises:
forming the raised locations as solder depots;
melting the solder depots in the depressions when the individual semiconductor chips have been stacked.

25. The method according to claim 24, which comprises
centering joining locations with respect to one another during the melting of the solder depots.

26. A manufacturing method, comprising:
providing at least two stacked semiconductor chips each having an active front side with semiconductor structures and a passive rear side without any of the semiconductor structures, the passive rear side having at least two depressions formed therein;
disposing at least two raised locations on the active front side of each of the semiconductor chips, the raised locations
corresponding to the depressions on the passive rear side of a directly adjacent one of the semiconductor chips; and
joining the raised locations by at least one of adhesively bonding and soldering to the depressions.
